(19) United States
(12) Patent Application Publication
(10) Pub. No.: US 2018/0212306 A1
(43) Pub. Date: Jul. 26, 2018

(54) ANTENNAS FOR PLATFORM LEVEL WIRELESS INTERCONNECTS

(71) Applicant: Intel Corporation, Santa Clara, CA (US)

(72) Inventors: Adel A. ELSHERBINI, Chandler, AZ (US); Telesphor KAMGAING, Chandler, AZ (US); Sasha N. OSTER, Chandler, AZ (US); Brandon M. RAWLINGS, Chandler, AZ (US); Georgios C. DOGIAMIS, Chandler, AZ (US)

(21) Appl. No.: 15/746,364

(22) PCT Filed: Sep. 25, 2015
(86) PCT No.: PCT/US2015/052496

§ 371 Date: Jan. 19, 2018

(51) Int. Cl. H01Q 1/22; H01Q 9/04

(52) U.S. Cl. CPC H01Q 1/2283; H01L 2223/6677; H01Q 9/0457

(57) ABSTRACT

Antennas are described for platform level wireless interconnects. In one example, a substantially flat package substrate has an attached radio. A conductive transmission line on the package substrate is electrically connected to the radio and an antenna is attached to the package substrate connected to the conductive transmission line, the antenna radiating to the side of the package.

### FIELD

The present description pertains to antennas for communication between integrated circuit packages and in particular to antennas with radiation patterns for directing radiation towards the side.

### BACKGROUND

In multiple CPU servers, multiple CPU high performance computers, and other multiple chip systems, direct high speed communication between different CPUs or between CPUs and other system components can greatly enhance the overall system performance. Direct communication reduces the communication overhead and the latency. This is particularly true for usage scenarios in which the data is written to shared memory pools. Direct communication may be achieved by adding a switch or a switch matrix on the system board that carries the CPU's.

The connections to the switch can be made through the system board. This requires that the data is carried through the socket pins, for socketed CPUs. The number of socket connections is limited by the size of the socket. The data rate is also limited by the materials and interfaces between the CPU, the socket, and the system board. The connections to the switch may also be made using flex top side connectors. These connectors connect one chip to another directly with a dedicated cable avoiding the socket and the system board. Top side connectors provide higher data rates, but are more expensive. In addition, the package is more complex and assembly of the packages into a system is more complex because the cables must be placed and connected after all of the chips are in place.

### BRIEF DESCRIPTION OF THE DRAWINGS

Embodiments are illustrated by way of example, and not by way of limitation, in the figures of the accompanying drawings in which like reference numerals refer to similar elements.

FIG. 1 is a side view cross-sectional diagram of a wireless interconnect for chip-to-chip communications according to an embodiment.

FIG. 2 is a cross-sectional side view diagram of an alternative configuration of a package with a wireless interconnect according to an embodiment.

FIG. 3 is a block diagram of a radio chip and related components according to an embodiment.

FIG. 4 is a top view diagram of a package with multiple wireless interconnects for chip-to-chip communications according to an embodiment.

FIG. 5 is block diagram of a computing system with multiple high speed interfaces according to an embodiment.

FIG. 6 is an isometric transparent view of a tapered slot antenna for side radiation according to an embodiment.

FIG. 7 is an isometric transparent view of an alternative tapered slot antenna for side radiation according to an embodiment.

FIG. 8 is an isometric transparent view of a patch antenna and die cover for side radiation according to an embodiment.

FIG. 9 is a cross-sectional side view of the patch antenna and die cover of FIG. 8 according to an embodiment.

FIG. 10 is an isometric transparent view of a tapered antenna for use within package layers for side radiation according to an embodiment.

FIG. 11 is an alternative isometric transparent view of the tapered antenna of FIG. 10 according to an embodiment.

FIG. 12 is a cross-sectional side view of the tapered antenna of FIG. 10 according to an embodiment.

FIG. 13 is an isometric view of a chip antenna mounted to a package substrate for side radiation according to an embodiment.

FIG. 14 is cross-sectional side view diagram of a wireless interconnect for chip-to-chip communication through waveguides according to an embodiment.

FIG. 15 is a block diagram of a computing device incorporating wireless interfaces according to an embodiment.

### DETAILED DESCRIPTION

Wireless interconnects are used as described herein between the CPUs, between the CPU and a switch, and between the CPUs and other chips. The switch may demodulate and downconvert all the wireless signals and then retransmit them. Alternatively, the switch may use direct passband or passive switching, such as free space reflectors, lenses, and waveguides. Reflectors and other passives may even be attached to the system board or to a case or other housing. With millimeter waves, the propagation is very similar to that of optical propagation with well-defined propagation paths between the nodes. The waves are highly directional but not as sensitive to alignment as is the case with free space optics. In addition millimeter wave carriers are able to provide very high data rates, such as 160 Gbps or more, with less power consumption than laser diodes.

Copper traces through sockets and system boards are limited by the available space and routing layers. The copper traces are not ideal signal carriers and the many interfaces from pin to via to layer cause signal degradation, reflection, noise and interference. Millimeter-wave wireless transceivers can be implemented using advanced CMOS (Complementary Metal Oxide Semiconductor) processes. These transceivers can be made small compared to a CPU and require very little space on a large CPU or chipset package. As a result many transceivers can be integrated on or into a package with a CPU or chipset die without significantly increasing the size of the package. In addition, the space required is less than that required for optical and flexible (a.k.a. flex) cable connectors. Even when active repeaters are used, very little space is required for a demodulator, re-modulator and amplifier system for short distances in millimeter wave.

The assembly of multiple packages in a single system is easier with wireless connectors than with cable and optic fiber because the radio signals can cross each other without coupling and interfering. This makes it much simpler to create mesh networks. In addition to the wave beams being crossed, they may also be steered. If the packages are placed appropriately, each CPU can communicate with any other CPU using the same set of antennas by steering the millimeter wave beams with a phased array or other device. Steering or directed antennas also allow for communication with packages that are out of the plane of the transceiver. Communication may be directed in any of three dimensions so that, for example a CPU on a motherboard may communicate with a storage blade above the motherboard or even with external devices which are sufficiently close by.

Two main components may be used for many of the described implementations. Wireless millimeter wave nodes on at least two CPUs or other packages and a wireless switch. The millimeter wave nodes have a millimeter wave radio die and an antenna. The millimeter wave radio die can be part of a CPU package in the same or a different die from the CPU. The radio may also be in a separate package with a connection to the CPU or other die. The nodes can be dedicated to a CPU, memory, nonvolatile storage, chipset or any other desired high speed die or device. The nodes do not have to be on the same motherboard as the switch or as each other. One of the two nodes may be on a different motherboard or on a chassis component. One advantage of the wireless communications and the switch is that there may also be many more than two nodes.

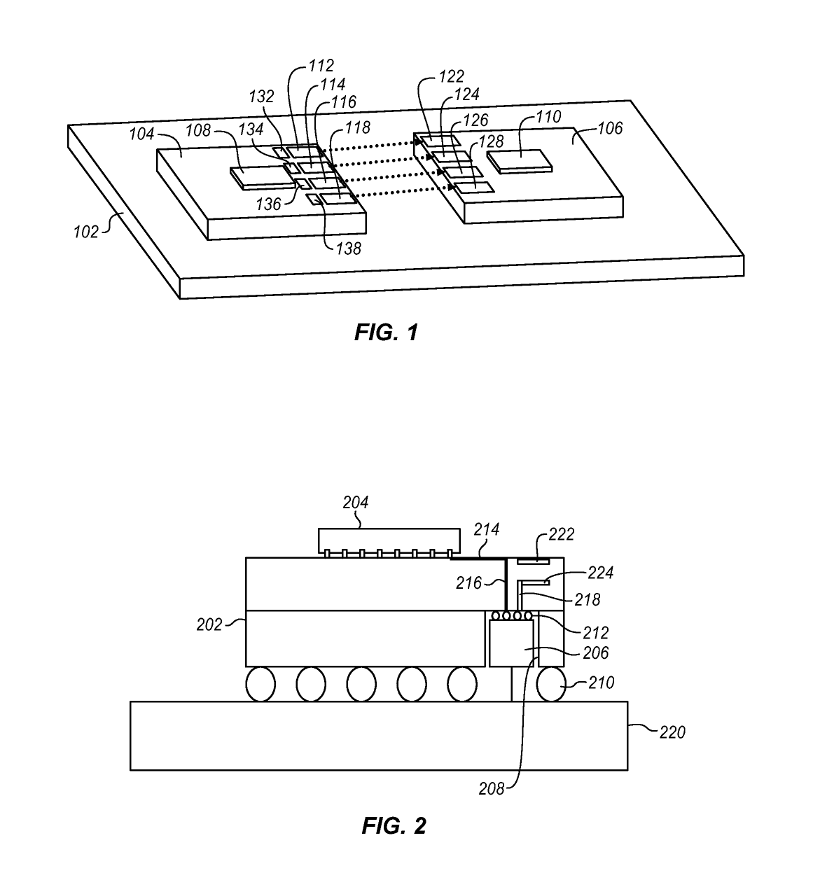

In wireless chip-to-chip or chip-to-switch communication within a platform, side radiating antennas may be used to provide direct line of sight communication to nearby components, as shown for example in FIG. 1. To achieve radiation directed towards the side, new antenna structures are needed to ensure that the maximum radiation direction is sideways and to minimize the radiation in the other directions.

FIG. 1 is a general isometric view diagram of one example of a wireless interconnect using antennas for chip-to-chip communication or for free space optics. A first 108 and second 110 chip are each mounted to a respective package 104, 106 using a ball grid array (BGA), land grid array (LGA), or other connection system including pads, wire leads, or other connectors. The packages are mounted to a printed circuit board (PCB) 102, such as a motherboard, system or logic board or daughter card using a solder ball array or any other desired system. The packages are electrically connected to external components, power, and any other desired devices through traces (not shown) on or in the PCB. The chips may also be connected to each other through the PCB. The packages may be mounted to the PCB using sockets (not shown), depending on the particular implementation.

The first and second packages 104, 106 are discussed herein as being central processing units and, in particular, as server CPUs. However, the techniques and configurations described herein may be applied to many different types of packages for which a high-speed communications link would be suitable. In some implementations, the package may include many different functions such as with a System-in-Package (SiP). In other implementations, the packages may be memory, a communications interface hub, a storage device, co-processor or any other desired type of package. In addition, the two packages may be different so that one may be a CPU and the other may be a memory or a chipset, for example.

Each chip is also connected through the package to a set of radios 132, 134, 136, 138. The first package 104 has external radios, while in the second package 106, the radios are integrated into the chip 110. The radios may be formed of a single die or a package with multiple dies or using another technique. Each radio is mounted to the package near the edge of the package that is near to the other chip. The package may include copper traces, lines, or layers to connect particular lands, pads, or solder balls of the chip to the radio die for data and control signals. The radio die may also be connected to the chip to provide power to the radio die. Alternatively, the radio die may obtain power from an external source through the package connection to the PCB.

A set of antennas 112, 114, 116, 118 is mounted to the first package 104 and each coupled to a respective radio 132, 134, 136, 138. Another set of antennas 122, 124, 126, 128 is mounted to the second package 106. Each antenna is coupled to a respective radio portion of the chip 110. Extremely small antennas may be used that are integrated onto or into the package substrate. The antennas are configured so that when the packages are mounted to the PCB, the antennas are directed to each other. The short distance between the antennas allows for a low power and low noise connection between the two chips. The wireless interconnect reduces the complexity of the socket and the complexity of the motherboard for the computing platform.

While different frequencies may be used to suit particular implementations. Millimeter wave and sub-THz frequencies allow for an antenna that is small enough to be integrated on the same package that is normally used for the chip. The antennas may also be constructed using the same materials that are used in the fabrication of the package substrate and still exhibit good electrical performance.

In some embodiments, a server may be constructed with multiple CPUs. Each CPU may be mounted to a package with multiple parallel radio die and antenna sets to provide multiple parallel channels within the server between the two CPUs. The small antenna size permitted for millimeter-wave signals allows each antenna of the package for one of the CPUs to be directed to a corresponding antenna on the package for the other CPU. This configuration may be used to combine parallel radio connections and provide Terabit per second data rates.

In some embodiments, a broadband wireless interconnect may be used. For example with a radio operating in a radio frequency range of from 100-140 GHz, the size of each antenna including the keep out zone can be as small as 1.25×1.25 mm to 2.5×2.5 mm. The actual antenna may be still smaller. Considering a typical server CPU package, more than 30 antennas of 1.25×1.25 mm may be placed along one edge of the package. This would allow more than 30 separate links each carrying 40-80 Gb/s each over a short distance. The separate links may all be used to communicate with a single second chip as shown in FIG. 1 or there may be different package antennas placed next to different antennas of the CPU package. This allows the CPU package to communicate with different chips using different links.

In addition to the simple point-to-point connection of FIG. 1, point-to-multi-point transmission may also be provided without using an external switch matrix. The antennas of multiple chip packages may be positioned within range of the antenna or antennas of one of the CPU packages. The multiple chip packages may all receive the same signal from the CPU package at the same time. In order to control which one of the multiple chip packages receives a transmission, the radio and antenna system may include beam steering.

FIG. 2 is a cross-sectional side view diagram of an alternative configuration of a package with an ultra high speed radio transceiver. As compared to the example of FIG. 1, in this example, the radio and the antennas are placed in different positions within the layers of a package substrate 202. This approach allows the footprint or top surface area of the package to be reduced but may cause the package to be taller.

A package or package substrate 202 has an integrated circuit chip 204 attached to a top side using a solder ball, land grid, pad, or any other suitable connection system. The chip in this or any other example may be a CPU, a memory, an interface or communications hub, or any other integrated circuit or data device. The substrate has a cavity 208 on the opposite side of the substrate. This is shown as the bottom side as compared to the top side which carries the integrated circuit chip. The bottom side includes a solder ball 210 or other type of connection to the system board 220. As in the other examples, the package 202 may connect to a system board through a socket, daughter card or in any of a variety of other ways. A radio 206 is attached to the opposite side of the substrate inside the cavity 208 using a solder ball, land grid, pad or any other suitable connection system.

The top side chip 204 is coupled through a few of its output pads to surface traces 214 on the top side of the substrate 202. These traces connect to vias 216 through the substrate that connect to the connection pads in the cavity to connect the top side chip to the radio 208. The radio may be coupled in another way but the vias provide a quick and direct connection through the package substrate to the radio. The radio then connects again through vias 218 from its connection pads to antennas. In this example, one antenna 222 is in a layer near the top side of the substrate and another antenna 224 is embedded within the substrate. The top side antenna may be easier to fabricate while the embedded antenna may provide for a smaller package footprint. All of the antennas may be on the top side of the package or all of the antennas may be embedded into the package or a mix may be used as shown here.

FIG. 3 is a block diagram of an example of a transceiver or radio chip system architecture and connected components that may be used for the wireless interconnect described herein. The transceiver chip may take a variety of other forms and may include additional functions, depending on the particular implementation. This radio design is provided only as an example. The radio chip 350 is mounted to the package substrate 352 to which the primary integrated circuit die or chip 202, 203 is also mounted as shown in FIG. 1. The substrate 352 is mounted to the PCB or motherboard. The radio package may include a local oscillator (LO) 302 or a connection to an external LO and optionally a switch that allows the external LO feed to be used instead of or in addition to the internal LO. The LO signal may pass an amplifier and multiplier, such as an active doubler 308 and 0/90° quadrature hybrids 310 to drive an upconverter and mixers 314.

The RX (receive) chain 320 may contain a receive antenna 356 in the package coupled to a low noise amplifier (LNA) 322 and a wideband baseband (BB) amplification chain 324 with downconverters 312 for analog to digital conversion. The TX (transmit) chain 340 may include a BB digital driver chain 342 to the upconverters 314, and a power amplifier (PA) 344 to the transmit antenna 358. There may be multiple transmit and receive chains to transmit and receive over multiple channels simultaneously. The various channels may be combined or consolidated in different ways, depending on the particular implementation.

The TX and RX chains are both coupled through the substrate to the antenna. There may be a single antenna for TX and RX or there may be separate RX and TX antennas as shown. The antennas may be designed to have different radiation patterns to suit different wireless connections. This may allow the chip to communicate with multiple antennas in different locations on the motherboard. A narrow beam transmit and receive pattern allows power to be concentrated in a single direction for communication with just one other device.

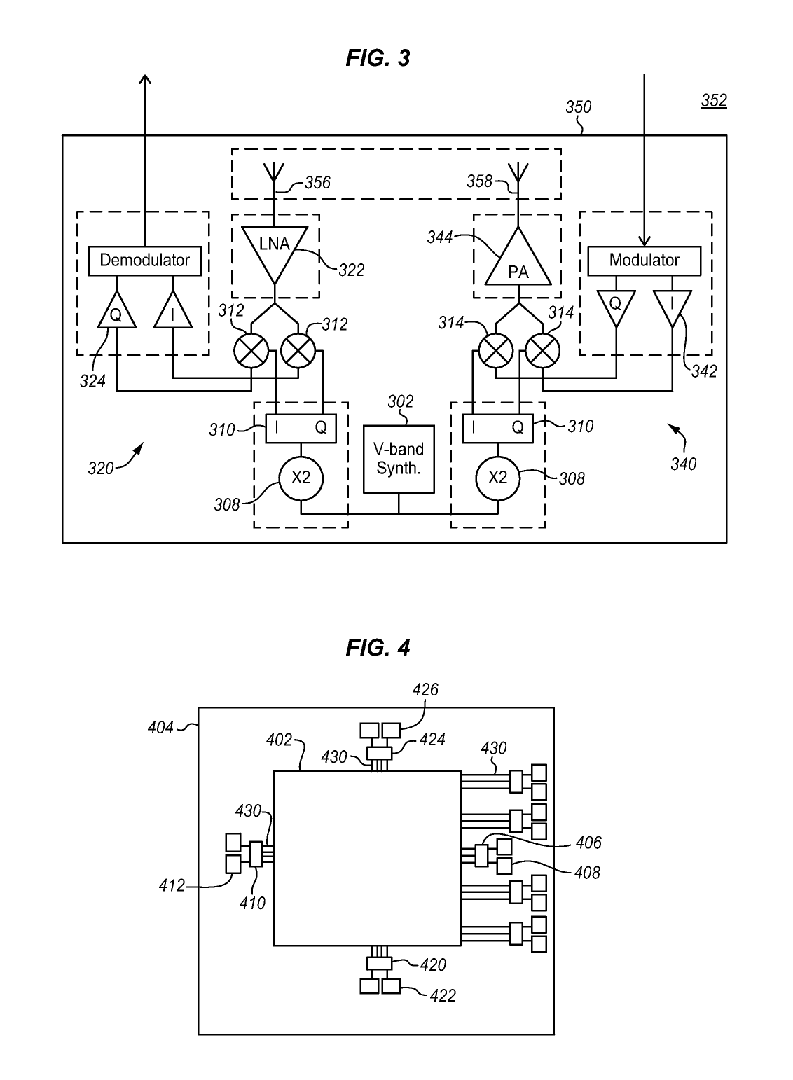

FIG. 4 is a top view diagram of an example of an implementation of multiple wireless interconnects on a single microserver package. In this example, separate antennas are used to transmit and receive, but it is also possible to share the antenna between the Tx and the Rx chains. The antenna size may vary from 1.25×1.25 mm or less to 2.5×2.5 mm or more depending on the carrier frequency, desired gain, and transmission range.

A single integrated circuit chip or die 402 includes both processing and baseband systems and is mounted to a package 404. The baseband sections of the chip are coupled through on-package traces 430 to radio chips or dies which are in turn coupled through the package to antennas. In this example, the integrated circuit chip is a CPU for a microserver and is rectangular. There are radio chips on each of the four sides of the CPU. The sides shown as top, left, and bottom in the drawing figure each have a respective radio 424, 410, 420 coupled to a respective Tx, Rx antenna pair 426, 412, 422. The side shown as the right side shows five radios each connected to a respective antenna pair. The number of radios and antennas on each side may be determined based on communication rate needs in each direction.

Very few high speed links may be required on a microserver package. A single link is able to deliver data rates in excess of 40 Gb/s across a distance of a few cm. The data rate may still be on the order of 5-10 Gb/s for transmission distances of up to 50 cm.

FIG. 4 shows many wireless links implemented on the same side of one package. This allows the aggregate data rate to be increased. Alternatively, the data may be sent to different other devices that are in the same general direction. Both the radio chips and the antennas are placed towards the edge of the package to limit obstructions in the radio path that may come from heat sinks and heat spreaders. In general the losses for a copper trace baseband signal are much lower than the losses through the same copper trace for an RF (radio frequency) signal. As a result, the radio chips may be kept very close to the antenna. This limits electrical signal and power losses due to the RF routing through the substrate. The radio chip may be installed onto the package in any manner desired and may even be embedded in or a part of the substrate. By using multiple radios, the on-package mm-wave wireless interconnects can be scaled for extremely high data rate applications. This may be useful in systems such as servers and media recording, processing, and editing systems. As shown, multiple links can be put together to achieve data-rates close to a Tb/s.

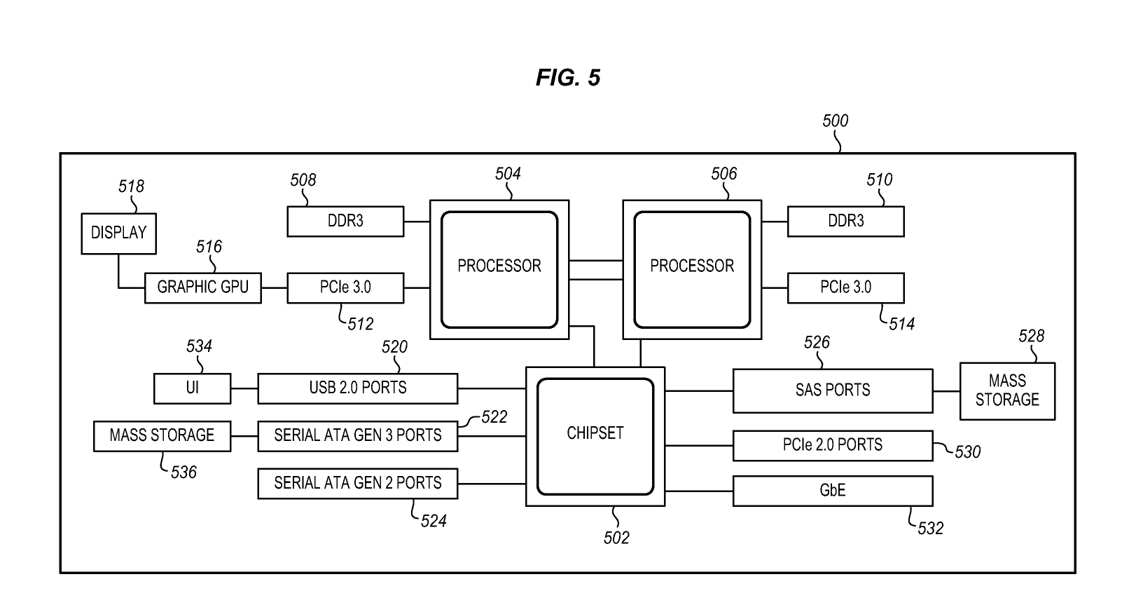

FIG. 5 is a block diagram of a computing system 500 with multiple high speed interfaces that may be implemented using the wireless connections as described herein. The computing system may be implemented as a server, microserver, workstation, or other computing device. The system has two processors 504, 506 having multiple processing cores although more processors may be used, depending on the particular implementation. The processors are coupled together through a suitable interconnect such as the wireless interconnect described herein. The processors are each coupled to a respective DRAM (Dynamic Random Access Memory) module 508, 510 using a suitable connection, such as the wireless connection described herein. The processors are also each coupled to a PCI (Peripheral Component Interconnect) interface 512, 514. This connection may also be wired or wireless.

The PCI interfaces allow for connections to a variety of high speed additional components such as graphics processors 516 and other high speed I/O systems for display, storage and I/O. The graphics processor drives a display 518. Alternatively, the graphics processor is core or a die within one or both of the processors. The graphics processor may also be coupled to a different interface through a chipset.

The processors are also both coupled to a chipset 502 which provides a single point of contact for many other interfaces and connections. The connection to the chipset may also be wired or wireless, one or both of the processors may be connected to the chipset, depending on the implementation. As shown, a processor 504 may have a wireless connection to one or more processors 506, memory 508, peripheral components 512, and a chipset 502. These connections may all be wireless as suggested by the multiple radio and antennas of FIG. 4. Alternatively, some of these connections may be wired. The processor may have multiple wireless links to the other processor. Similarly the chipset 502 may have wireless connections to one or more of the processors as well as to the various peripheral interfaces as shown.

The chipset is coupled to USB (Universal Serial Bus) interface 520 which may provide ports for connections to a variety of other devices including a user interface 534. The chipset may be connected to SATA (Serial Advanced Technology Attachment) interfaces 522, 524 which may provide ports for mass storage 536 or other devices. The chipset may be connected to other high speed interfaces such as a SAS (Serial Attached Small computer serial interface) interface 526 with ports for additional mass storage 528, additional PCI interfaces 530 and communications interfaces 532, such as Ethernet, or any other desired wired or wireless interface. The described components are all mounted to one or more boards and cards to provide the described connections.

The following diagrams provide different millimeter wave antenna structures in package substrates and in heatsinks that have high gain and can radiate sideways. In some embodiments, the antennas are able to radiate in two opposite polarizations which allows the data rate to be doubled using the same frequency bandwidth.

An antenna that radiates perpendicular or normal to the top surface of the package is not suitable for use for the application shown in FIGS. 1 and 2. For in-plane chip-to-chip communication a side radiating antenna provides a more useful distribution pattern.

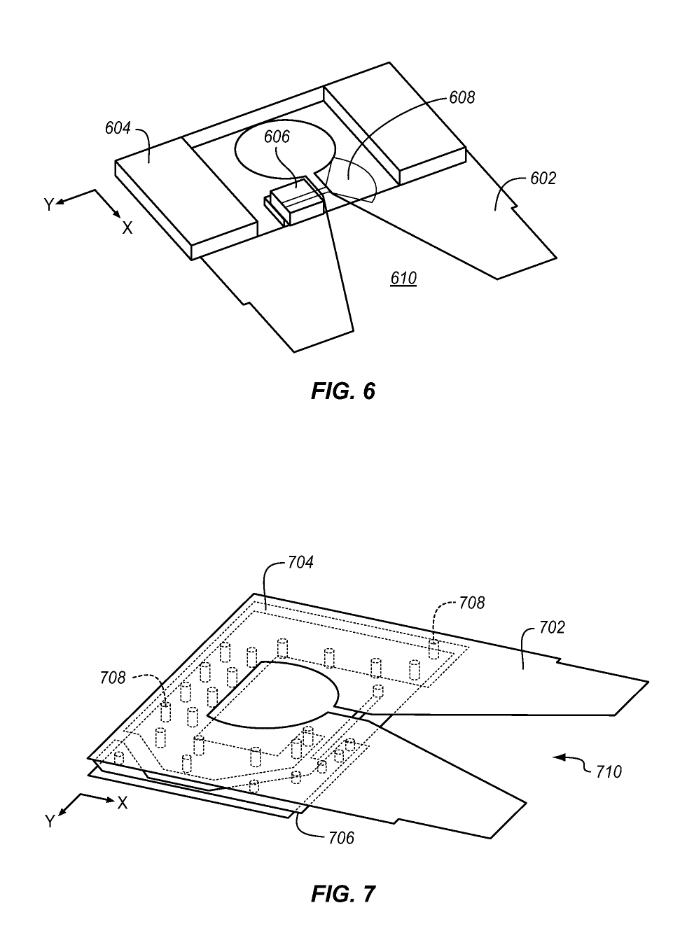

FIG. 6 is an isometric transparent view of a tapered slot antenna suitable for directing radiation towards the side of a package and that produces horizontal polarization at or near 120 GHz. Such a tapered slot antenna may be integrated on the side of a package or placed on top of a package. The antenna radiates horizontal polarization in an x-y plane as shown in FIG. 7 that is parallel to the package plane.

The antenna has a central strip line or microstrip 606 coupled to a transition 608 to a slot line 610. The slot line is defined by a lower V-shaped conductive plate 602 and an upper flat conductive plate 604. The top plate ends with distance from the strip line and the lower plate is flared with distance to the stripline to allow the waves to radiate. The stripline or microstrip is coupled to the radio to receive a modulation data signal.

Different tapering functions such as linear, exponential and elliptical can be used to achieve the desired radiation and bandwidth characteristics. The top layers of the antennas can be copper planes or another material depending on the particular implementation.

FIG. 7 is an isometric transparent view of a similar tapered slot antenna with an alternative construction. In this example, the stripline 706 is still mounted between upper 704 and lower 702 conductive plates. The stripline conducts the modulated radio signals into a taper 710. However, in this example, the tapered slot is not formed of solid panels as in FIG. 6 but with an array of conductive posts 708 placed in a pattern in the space between the upper and lower plates. The conductive posts may work as well but are easier to form using standard substrate processing technologies. Furthermore, depending on the package technology used, a similar structure can be implemented in the plane perpendicular to the package and provide the orthogonal polarization.

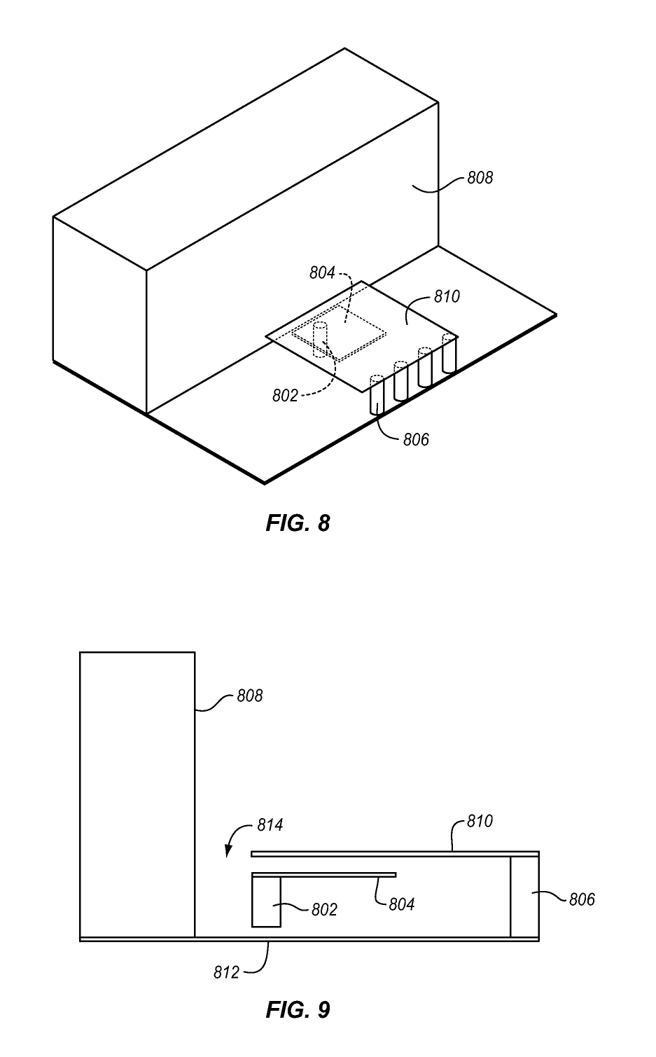

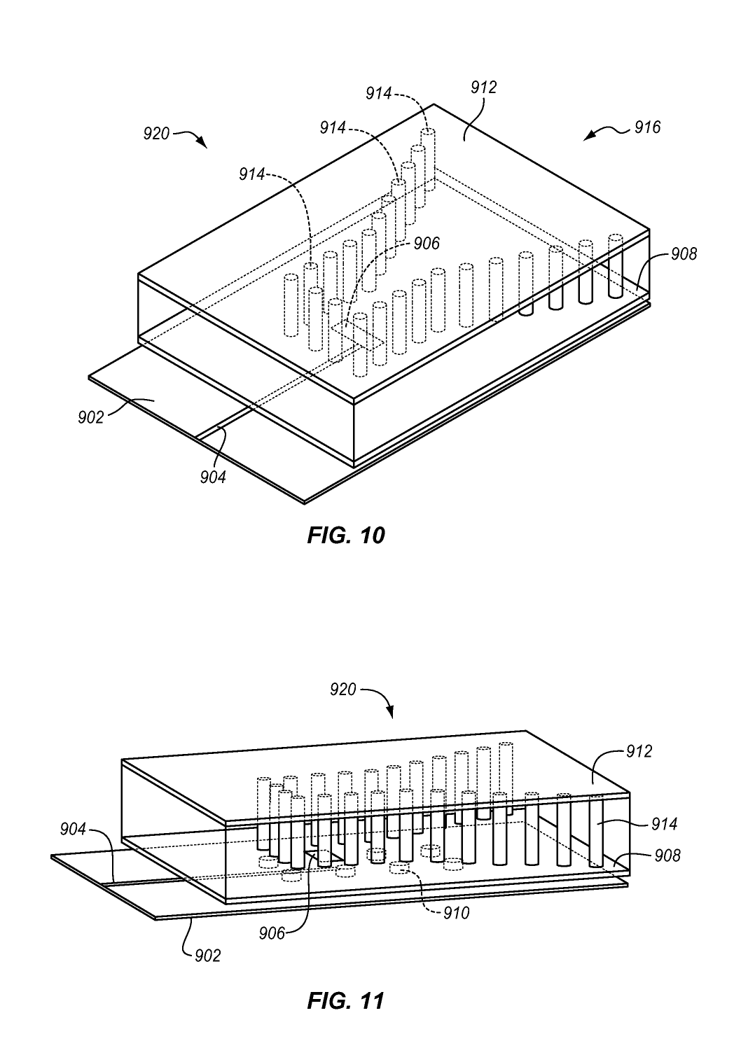

FIG. 8 is an isometric transparent view of a standard or shorted capacitively coupled patch antenna suitable for use with the described packages. FIG. 9 is a cross-sectional side view of the same antenna for directing radiation sideways from a package to another component. The standard or a shorted patch antenna of FIGS. 8 and 9 uses the edge of the heatsink as a reflector to direct the radiation away from the antenna as shown in FIG. 10. Part of the power is radiated upwards but a significant portion of the radiation is radiated to the side of the package compared to the same antenna without the reflector. The side of the heat sink can be shaped or sculpted to provide even more directivity.

Referring to FIGS. 8 and 9, the modulated radio frequency (RF) data is fed to the antenna through a feed via 802. The feed via channels the energy along a bottom patch 804 within a chamber that is defined by a floor 812 below the bottom patch, a top patch 810 above the bottom patch, a set of shorting vias at one end of the chamber and a vertical reflector 808 at the opposite end of the chamber. The characteristics of the chamber may be tuned to suit the particular frequency and modulation characteristics of the incoming RF energy. The chamber is primarily planar along the surface of the substrate and has an upper port 814 through which the energy is supplied. This port is against the vertical surface of the reflector so that the energy is constrained from going toward the reflector and a significant part of the energy propagates horizontally or to the side away from the vertical reflector.

The vertical reflector may take any of a variety of different forms. A vertical conductive surface may be attached to the substrate or formed as part of the antenna. Alternatively, the cover for the package may be used. The cover may be a simple protective cover sealed over the electronic and other components for external protection. The reflector may also be a heat sink for the chip such as an integrated heat spreader or similar type of component.

FIGS. 10, 11, and 12 show an alternative side radiating antenna design. As shown, rectangular or ridged waveguides can be integrated into a package to provide vertical polarization. The integrated waveguide antenna is tapered to create a horn-like structure in the package. Several transition structures can be implemented to allow different bandwidths and substrate materials.

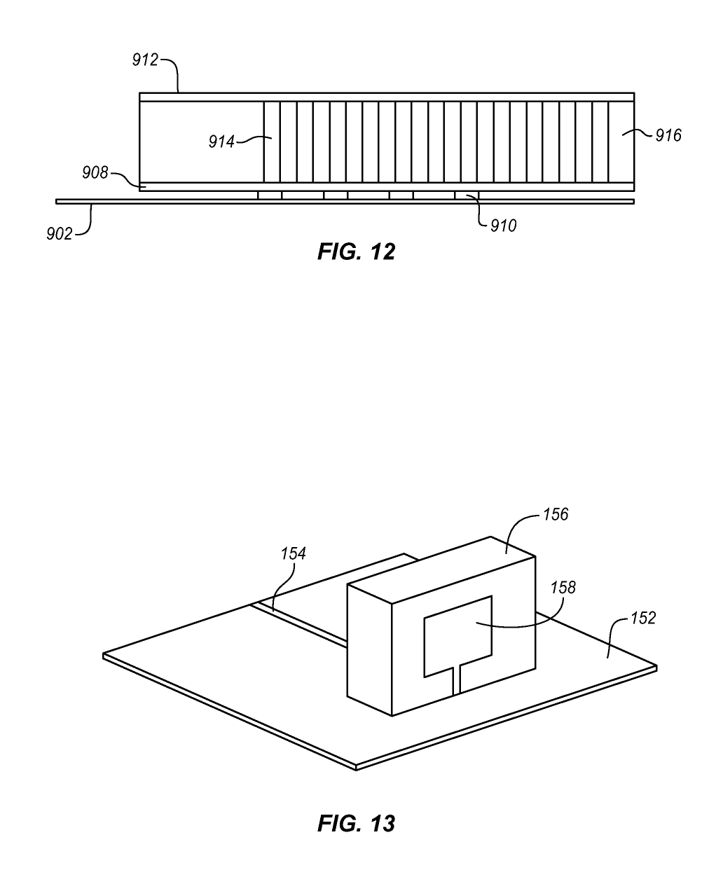

FIG. 10 is an isometric transparent view of an antenna 920 with the transmission direction away from the page. FIG. 11 is an isometric transparent view mostly from the side of the same antenna 920 from the side. FIG. 12 is a side view of the same antenna 920. The antenna sits on a substrate 902 which may be a top layer of a package substrate or it may be an intermediate layer. The substrate may be formed of any of a variety of dielectric materials including polymers, oxides and resins. A transmission line 904 is formed on the substrate and, for transmission, it conducts the modulated data signal from a radio to the antenna. For reception, it carries the modulated data signal from the antenna to the radio.

The antenna is formed on the substrate with a bottom ground surface 908 over the substrate and a top ground surface 912 over and spaced apart from the bottom ground surface. These surfaces are formed from a conductive material which may be a deposited layer or an applied sheet. A coupling aperture 906 between the top and bottom layers connects the transmission line to the interior of the horn structure. A wall 914 is formed on either side of the coupling aperture. The wall tapers out to an exit/entrance port 916 at the end of the waveguide horn. The port sends and receives the millimeter wave signals with a specific polarization, either vertical or horizontal. The wall 914 may be formed from solid conductive sheets or layers, but in this case is formed by a series of posts. These posts may easily be formed in a package substrate using drilling or etching and filling technologies used for vertical signal vias. With the posts at an appropriate separation, they will appear as a solid wall to RF signals within a particular frequency range.

As mentioned above, the horn-like waveguide antenna may be formed within a package substrate or it may be fabricated separately and then attached to a top or bottom surface of a package substrate. In some applications, an external mounted chip antenna might provide better performance. For example, at high operating frequencies, the package material might cause significant losses. An external chip antenna allows a low loss antenna substrate to be used instead of a conventional high loss package substrate. In other applications, the routing space on or in a package might be limited. Chip antennas may use less area inside the package than integrated antennas would. The chip antenna may be designed for use with a particular package to provide the best total electrical performance.

The antenna of FIGS. 10, 11, and 12 may be fabricated using SIW (Substrate Integrated Waveguide) technology. The SIW horn antenna may then be mounted on the package 902 using standard SMT (Surface Mount Technology) solder assembly. The transition from the package routing to SIW may be done using standard solder bumps 910 between the horn antenna and the package substrate. The solder bumps may also be used to provide an electrical ground connection for the top and bottom ground planes 912, 908. If the horn antenna is formed in the substrate, then there may not be any solder bumps, depending on the particular implementation.

FIG. 13 is an isometric view of an alternative type of chip antenna mounted to a package substrate, where a vertical microstrip antenna is formed above the top surface of the main package either by assembling the chip antenna onto the package or by additive manufacturing such as 3D-printing. In this example a patch antenna 158 is mounted inside a housing 156. The housing is mounted on a package 152 over a transmission line 154. The transmission line is deposited, printed, or pressed onto the package. The antenna housing is attached so that the antenna feed line connects to the transmission line. The transmission line on the package connects to a radio (not shown) to receive and transmit the millimeter wave signals.

The patch antenna 158 is directly coupled to the package using SMT or any other suitable technology. The antenna may be attached to the top or the bottom of the package, depending on the overall structure of the package and the system board configuration. For millimeter wave systems, the patch antenna and housing may be 2×2×1 mm in size or smaller or larger depending on the operating frequency so that many such patch antennas may be used on the same package as suggested by FIG. 4. Similar structures to the chip antenna 158, 920 may be printed directly on top of the package. Additive or 3D printing may be used as well as other techniques. Additive printing allows precise alignment and allows complex antenna structures or antennas to be fabricated with integrated lenses and other complex structures.

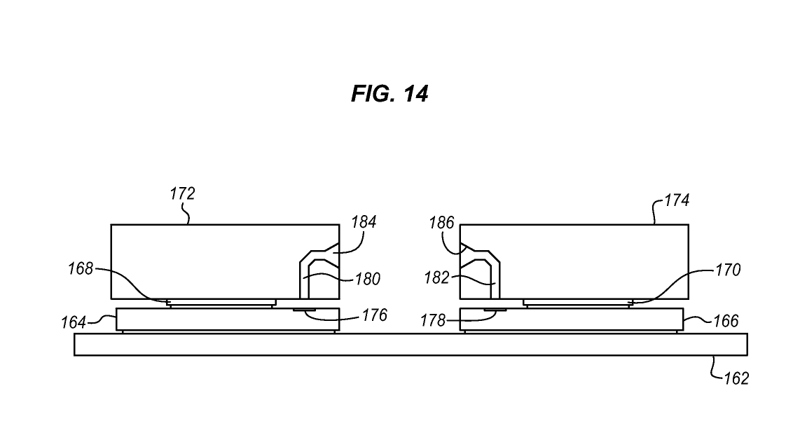

FIG. 14 shows another approach to side-radiating antenna structures that also uses a heat sink or other structure mounted over or under the package substrate. In this case, a heat sink is used. At millimeter wave, an appropriate waveguide is small relative to the size of a package, e.g. a few millimeters across. This allows guiding structures to be created inside a heatsink without significantly impacting the heat dissipation performance of the heat sink.

In FIG. 14 a portion of a system board or motherboard 162 has two packages 164, 166 mounted to its surface using sockets, SMT, ball or land grid arrays or any other technology. The substrates each carry a respective integrated circuit die 168, 170 which may be a processor, a communications interface, a memory, a graphics processor, or any other type of die. The dies are both covered by a heat sink 172, 174. The heat sinks are thermally coupled to the respective die in any of a variety of suitable ways. Both packages have a small antenna 176, 178 on the surface of the package that is coupled to a radio die (not shown) on the package or within the main die.

The small antennas 176, 178 on the package couple the energy to and from a waveguide 180, 182 in the respective heatsink. The waveguides have a vertical guide to collect the signals and move them up from the package surface. The waveguides each have an elbow which then directs the RF signals sideways. From the elbow, the waveguides each include a horizontal horn section 184, 186 or other type of antenna which directs the RF signal toward the other package. The packages are positioned near each other and each horn is pointed directly at the other horn so that the RF signal may be sent and received between the two horns. For a typical millimeter wave waveguide structure as shown, the straight waveguide sections are about 2×2 mm and the dimensions for the flare of the horns are 2-4 mm with square, rectangular, elliptical or circular shapes. These dimensions may be adapted to suit different carrier frequencies for different applications. The sizes of the waveguides are increased and shown out of scale to better show the features of the invention. Different horn and other tapering and guiding shapes may be used to suit different signal types and different heat sink materials. The horns in this case may support vertical and/or horizontal polarization. However different shapes may be used to allow only one type of polarization or to put other restrictions on the signals.

While FIGS. 1 and 14 shows that two packages communicate using identical antenna structures, this is not required. Each package may be fabricated using an antenna structure that best suits the particular package and that is able to make an RF connection to another package. Different packages may use different antenna structures provided that both structures are able to send and receive the same waveform, modulation, and polarization.

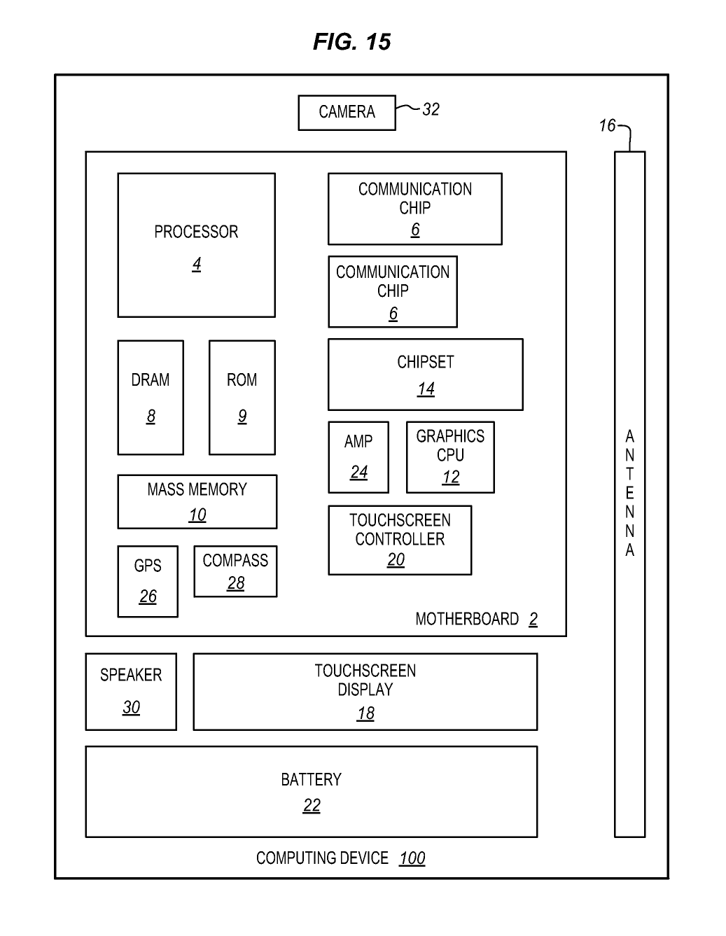

FIG. 15 illustrates a computing device 100 in accordance with another implementation. The computing device 100 houses a board 2. The board 2 may include a number of components, including but not limited to a processor 4 and at least one communication chip 6. The processor 4 is physically and electrically coupled to the board 2. In some implementations the at least one communication chip 6 is also physically and electrically coupled to the board 2. In further implementations, the communication chip 6 is part of the processor 4.

Depending on its applications, computing device 11 may include other components that may or may not be physically and electrically coupled to the board 2. These other components include, but are not limited to, volatile memory (e.g., DRAM) 8, non-volatile memory (e.g., ROM) 9, flash memory (not shown), a graphics processor 12, a digital signal processor (not shown), a crypto processor (not shown), a chipset 14, an antenna 16, a display 18 such as a touchscreen display, a touchscreen controller 20, a battery 22, an audio codec (not shown), a video codec (not shown), a power amplifier 24, a global positioning system (GPS) device 26, a compass 28, an accelerometer (not shown), a gyroscope (not shown), a speaker 30, a camera 32, and a mass storage device (such as hard disk drive) 10, compact disk (CD) (not shown), digital versatile disk (DVD) (not shown), and so forth). These components may be connected to the system board 2, mounted to the system board, or combined with any of the other components.

The communication chip 6 enables wireless and/or wired communications for the transfer of data to and from the computing device 11. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 6 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 11 may include a plurality of communication chips 6. For instance, a first communication chip 6 may be dedicated to shorter range wireless communications such as Wi-Fi and Bluetooth and a second communication chip 6 may be dedicated to longer range wireless communications such as GPS, EDGE, GPRS, CDMA, WiMAX, LTE, Ev-DO, and others.

In some implementations, any one or more of the components may be adapted to use the wireless connections described herein. The features of the system of FIG. 15 may be adapted to that of FIG. 7 and vice versa. For example, the system of FIG. 15 may carry multiple processors. The system of FIG. 5 may include any one or more of the peripherals shown in FIG. 15. The term “processor” may refer to any device or portion of a device that processes electronic data from registers and/or memory to transform that electronic data into other electronic data that may be stored in registers and/or memory.

In various implementations, the computing device 11 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 11 may be any other electronic device that processes data including a wearable device.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to an apparatus that includes a substantially flat package substrate, a radio attached to the package substrate, a conductive transmission line on the package substrate electrically connected to the radio and an antenna attached to the package substrate connected to the conductive transmission line, the antenna radiating to the side of the package.

Further embodiments include a central processing unit attached to the package substrate and wherein the radio is connected to the central processing unit.

In further embodiments the radio is formed on a die with the central processing unit.

In further embodiments the antenna is formed between layers of the package substrate.

In further embodiments the conductive transmission line is on a surface of the package substrate and the antenna is on the same surface of the package substrate.

In further embodiments the antenna is formed on the package substrate using deposition.

In further embodiments the antenna is formed as a chip antenna and attached to the same surface of the package substrate.

In further embodiments the antenna is formed using substrate integrated waveguide technology.

Further embodiments include a central processing unit attached to the package substrate and a heat sink over the central processing unit, wherein the radio is connected to the central processing unit, and wherein the heat sink comprises a waveguide coupled to the antenna to guide radio frequency energy between the waveguide and an external component.

In further embodiments the waveguide comprises a vertical section normal to the package substrate coupled to the antenna and a horizontal section coupled to the vertical section and having a taper to direct signals from the radio to the external component.

In further embodiments the antenna comprises a top ground plane and a bottom ground plane and a tapered waveguide between the top and the bottom ground plane.

Further embodiments include tapered side walls between the top and bottom ground planes, the side walls being formed of separated conductive posts.

In further embodiments the posts are formed by drilling and filling the package substrate.

Further embodiments include a heat sink on the package substrate, the antenna being attached proximate the heat sink so that radio frequency energy is reflected from the heat sink to the side of the package.

Some embodiments pertain to an apparatus that includes a substantially flat package substrate, a radio attached to the package substrate, a conductive transmission line on the package substrate electrically connected to the integrated circuit, and a vertical microstrip antenna over the package substrate and the transmission line as a chip antenna attached to the package substrate the antenna radiating to the side of the package.

In further embodiments the vertical microstrip antenna is formed by additive manufacturing.

In further embodiments the vertical microstrip antenna comprises a patch antenna mounted inside a housing and wherein the patch antenna is attached to the package substrate using surface mount technology.

Some embodiments pertain to a computing system that includes a system board, a substantially flat package substrate attached to the system board, a central processing unit attached to the package substrate, a radio attached to the package substrate, a conductive transmission line on the package substrate electrically connected to the radio, a first antenna attached to the package substrate connected to the conductive transmission line, the antenna radiating to the side of the package, a cover over the package substrate and the central processing unit, and a chipset package attached to the system board, the chipset package including a second antenna for communication with the first antenna.

In further embodiments the cover comprises a waveguide coupled to the first antenna to guide radio frequency energy between the waveguide and the second antenna, the waveguide having a vertical section normal to the package substrate coupled to the first antenna and a horizontal section coupled to the vertical section and having a taper to direct signals from the radio to the second antenna.

In further embodiments the first antenna is attached proximate the cover so that radio frequency energy is reflected from the heat sink to the side of the package.

1. An apparatus comprising:
a substantially flat package substrate;
a radio attached to the package substrate;
a conductive transmission line on the package substrate electrically connected to the radio; and
an antenna attached to the package substrate connected to the conductive transmission line, the antenna radiating to the side of the package.

2. The apparatus of claim 1, further comprising a central processing unit attached to the package substrate and wherein the radio is connected to the central processing unit.

3. The apparatus of claim 2, wherein the radio is formed on a die with the central processing unit.

4. The apparatus of claim 1, wherein the antenna is formed between layers of the package substrate.

5. The apparatus of claim 1, wherein the conductive transmission line is on a surface of the package substrate and the antenna is on the same surface of the package substrate.

6. The apparatus of claim 5, wherein the antenna is formed on the package substrate using deposition.

7. The apparatus of claim 5, wherein the antenna is formed as a chip antenna and attached to the same surface of the package substrate.

8. The apparatus of claim 7, wherein the antenna is formed using substrate integrated waveguide technology.

9. The apparatus of claim 5, further comprising a central processing unit attached to the package substrate and a heat sink over the central processing unit, wherein the radio is connected to the central processing unit, and wherein the heat sink comprises a waveguide coupled to the antenna to guide radio frequency energy between the waveguide and an external component.

10. The apparatus of claim 9, wherein the waveguide comprises a vertical section normal to the package substrate coupled to the antenna and a horizontal section coupled to the vertical section and having a taper to direct signals from the radio to the external component.

11. The apparatus of claim 4, wherein the antenna comprises a top ground plane and a bottom ground plane and a tapered waveguide between the top and the bottom ground planes.

12. The apparatus of claim 11, further comprising tapered side walls between the top and bottom ground planes, the side walls being formed of separated conductive posts.

13. The apparatus of claim 12, wherein the posts are formed by drilling and filling the package substrate.

14. The apparatus of claim 1, further comprising a heat sink on the package substrate, the antenna being attached proximate the heat sink so that radio frequency energy is reflected from the heat sink to the side of the package.

15. An apparatus comprising:
a substantially flat package substrate;
a radio attached to the package substrate;
a conductive transmission line on the package substrate electrically connected to the integrated circuit; and
a vertical microstrip antenna over the package substrate and the transmission line as a chip antenna attached to the package substrate the antenna radiating to the side of the package.

16. The apparatus of claim 15, wherein the vertical microstrip antenna is formed by additive manufacturing.

17. The apparatus of claim 15, wherein the vertical microstrip antenna comprises a patch antenna mounted inside a housing and wherein the patch antenna is attached to the package substrate using surface mount technology.

18. A computing system comprising:
a system board;
a substantially flat package substrate attached to the system board;
a central processing unit attached to the package substrate;
a radio attached to the package substrate;
a conductive transmission line on the package substrate electrically connected to the radio;
a first antenna attached to the package substrate connected to the conductive transmission line, the antenna radiating to the side of the package;
a cover over the package substrate and the central processing unit; and
a chipset package attached to the system board, the chipset package including a second antenna for communication with the first antenna.

19. The computing system of claim 18, wherein the cover comprises a waveguide coupled to the first antenna to guide radio frequency energy between the waveguide and the second antenna, the waveguide having a vertical section normal to the package substrate coupled to the first antenna and a horizontal section coupled to the vertical section and having a taper to direct signals from the radio to the second antenna.

20. The computing system of claim 18, wherein the first antenna is attached proximate the cover so that radio frequency energy is reflected from the heat sink to the side of the package.
